(19) United States
(12) Patent Application Publication
(10) Pub. No.: US 2016/0079552 A1
(43) Pub. Date: Mar. 17, 2016

(54) PEROVSKITE SOLAR CELL

(71) Applicant: National Taiwan University, Taipei City (TW)

(72) Inventors: Wei-Fang SU, Taipei City (TW); Chun-Yu CHANG, Taipei City (TW); Cheng-Ya CHU, Taipei City (TW)

(21) Appl. No.: 14/706,207

(22) Filed: May 7, 2015

(30) Foreign Application Priority Data
Sep. 17, 2014 (TW) 103132034

(51) Int. Cl. H01L 51/44; H01L 51/42

(52) U.S. Cl. CPC H01L 51/447; H01L 51/426

(57) ABSTRACT

The present invention relates to a perovskite solar cell, which comprises a first electrode substrate; a perovskite material layer comprising a perovskite organic-inorganic material and a polymer additive, wherein the perovskite material layer is disposed above the first electrode substrate; and a second electrode, which is disposed above the perovskite material layer and corresponds to the first electrode substrate. The coverage of the perovskite material layer on the electrode or an electron-transport layer is significantly improved, and the roughness thereof is also decreased, thereby increasing the photoelectric conversion efficiency of the perovskite solar cell.

### CROSS REFERENCE TO RELATED APPLICATION

This application claims the benefits of the Taiwan Patent Application Serial Number 103132034, filed on Sep. 17, 2014, the subject matter of which is incorporated herein by reference.

### BACKGROUND OF THE INVENTION

1. Field of the Invention

The present invention relates to a perovskite solar cell, especially to a perovskite thin film solar cell having a planar heterojunction structure.

2. Description of Related Art

Solar energy is one of the highly regarded alternative energy sources. A solar cell is a device that converts light energy into electrical energy, and does not give off any greenhouse gases such as carbon dioxide or other undesirable substances when converting the energy, and posing no burdens to the environment. Therefore, solar cell development is in full swing, and the technology is becoming mature.

The solar cells are based on the principles of photovoltaic effect of semiconductor materials to convert light energy into electrical energy. Specifically, when light is incident upon semiconductor materials, photons are produced and give rise to electron-hole pairs in the semiconductor material. Then, the electrons and holes are transported to the two opposite electrodes respectively by the internal electric field, resulting in a voltage. At this time, when the two electrodes are connected to an external circuit, a current is generated.

According to the light-emitting principle of the solar cell, selection of the semiconductor material is quite important. Solar cells can be roughly classified into crystalline silicon solar cells, thin film solar cells, and dye-sensitized solar cells according to the types of semiconductor materials used. However, the above solar cells generally have the problems that their photoelectric conversion efficiency is difficult to improve or of high production cost. Thus, the popularization of solar cells and the application in power generation on a large scale are difficult.

Recently, a novel semiconductor material having a perovskite structure has been proposed, which has high photoelectric conversion efficiency, low production cost, and less pollution, and has become one of the highly regarded solar cells. In the past five years, the photoelectric conversion efficiency of the perovskite solar cells increases from 3.1% to 20.1%. Therefore, the development prospect of the perovskite solar cells is quite promising.

However, the perovskite layer in the thin-film solar cell with a planar heterojunction structure typically have poor coverage, resulting in a contact between the electron transport layer and the hole transport layer and poor electron transfer efficiency, thereby reducing the overall conversion efficiency.

Therefore, what is needed in the art is to provide a perovskite material having an improved coverage in the device having a planar heterojunction structure to enhance its photoelectric conversion efficiency.

### SUMMARY OF THE INVENTION

An object of the present invention is to provide a perovskite solar cell, featured by adding a polymer additive in a perovskite material layer in order to improve the coverage of the perovskite material layer on the electrode or an electron-transport layer, and decrease the roughness thereof, so as to enhance the photoelectric conversion efficiency.

The perovskite solar cell of the present invention includes: a first electrode substrate; a perovskite material layer comprising a perovskite organic-inorganic material and a polymer additive, wherein the perovskite material layer is disposed above the first electrode substrate; and a second electrode, which is disposed above the perovskite material layer and corresponds to the first electrode substrate.

According to one preferred embodiment of the present invention, the perovskite solar cell may further include an electron transport layer between the first electrode substrate and the perovskite material layer, and the electron transport layer may be made of a material capable of transporting electron effectively, so as to increase the charge mobility to the first electrode substrate. The electron transport layer may be made of conventional materials for electron transport layers including, but not limited to, an inorganic material, n-type organic small molecules or n-type polymers. For example, it may be made of titanium oxide (TiO₂), zinc oxide (ZnO), indium tin oxide (InSnOx), copper oxide (CuOx), alumina (Al₂O₃), zirconium oxide (ZrO₂), tin oxide (SnO₂), tungsten oxide (W0₃), niobium oxide (Nb₂O₅), cadmium sulfide (CdS), cadmium selenide (CdSe), cadmium telluride (CdTe), bismuth sulfide (Bi₂S₃), lead sulfide (PbS), indium phosphide (InP), or other n-type polymer, and preferably TiO₂. Since the perovskite solar cell of the present invention a solar cell with a planar heterojunction structure, the electron transport layer of the present invention is preferably a dense film. For example, when TiO₂ is used as the electron transport layer, the TiO₂ film is formed by coating a TiO₂ nanoparticle solution followed by a heat treatment at a low temperature, to provide a film with a thickness of 20 to 200 nm, and preferably 40 to 100 nm.

According to another preferred embodiment of the present invention, the perovskite solar cell may further include a hole transport layer between the second electrode and the perovskite material layer, and the hole transport layer may be made of an material capable of transporting hole effectively, so as to increase the charge mobility to the second electrode. The hole transport layer may be made of conventional materials for hole transport layers including, but not limited to, an inorganic material, p-type organic small molecules or p-type polymers. For example, it may be made of 2,2′,7,7′-Tetrakis(N,N-p-dimethoxyphenylamino)- 9,9-spirobifluorene (spiro-OMeTAD), poly(3,4-ethylenedioxythiophene)-poly(styrenesulfonate (PEDOT-PSS), N,N′-Bis(3-methylphenyl)-N,N′-bis(phenyl)benzidine (TPD), and poly(3-hexylthiophene) (P3HT), or other conductive polymers having a low band gap, and preferably spiro-OMeTAD. In addition, the hole transport layer may have a thickness of 50 to 500 nm, and preferably 150 to 250 nm.

Next, according to a preferred embodiment of the present invention, in the perovskite solar cell, the first electrode substrate is not particularly limited, and may be made of a transparent electrode material conventionally used in the art. For example, the transparent electrode material may be selected from the group consisting of: fluorine-doped tin oxide (FTO), indium tin oxide (ITO), ZnO—Ga₂O₃, ZnO-Al₂O₃, tin oxide, and zinc oxide. The first electrode substrate may have a thickness of 50 nm to 5 μm. When the first electrode substrate is FTO, the thickness may be preferably about 2.3 μm, while when the first electrode substrate is ITO, the thickness may be preferably about 150 nm. Furthermore, any conventional electrode materials in the art may be used as the second electrode, and it is not particularly limited. For example, the second electrode material may be selected from: copper, gold, silver, rubidium, palladium, nickel, molybdenum, aluminum, alloys thereof and multi-layer materials including the same. The second electrode may have a thickness of 10 to 300 nm, preferably 50 to 150 nm.

Furthermore, in accordance with a preferred embodiment of the present invention, the organic-inorganic perovskite material contained in the perovskite material layer may be made of a compound selected from at least one of compounds represented by Formula (I):

R₁R₂R₃NMX₃₋ₙYₙ (I)

wherein, R₁, R₂, and R₃ are each independently H, a linear C₁₋₁₀ alkyl, or a branched C₁₋₁₀ alkyl; M is Pb, Sn, Bi, Cu, Fe, Co, Ni, Mn, or Cd; X and Y are Cl, Br, or I respectively; and n is an integer of 0-3.

The organic-inorganic perovskite materials of Formula (I) is preferably CH₃NH₃PbI₃₋ₙClₙ, wherein n is an integer of 0 to 3.

According to a preferred embodiment of the present invention, the polymer additive contained in the perovskite material layer may comprise at least one hydrophilic polymer, wherein the hydrophilic polymer may be preferably at least one selected from the group consisting of: polyethylene glycol, polypropylene glycol, polyvinyl pyrrolidone, polylactic acid, polyvinyl alcohol, polyacrylic acid, polyurethane, polyethylene imine, polyacrylamide, poly(styrene sulfonic acid), and mixtures thereof, and more preferably polyethylene glycol. In addition, the hydrophilic polymer may have a molecular weight of 2K to 60K, and preferably 5K to 10K.

In the perovskite solar cells provided by the present invention, since the perovskite material layer is made of the perovskite organic-inorganic materials and the hydrophilic polymer, it can improve the coverage on the perovskite material layer, thereby effectively preventing contact of the two films on opposite sides of the perovskite material layer. For example, when the perovskite material layer is disposed between the electron transport layer and the hole transport layer, the contact therebetween can be avoided, thus solving the problem of inefficient electron transfer of the planar heterojunction of solar cells, and improving the photoelectric conversion efficiency.

To achieve a preferred coverage on the perovskite material layer, the polymer additives may be present in an amount from 1 to 10 wt % in the perovskite material layer. When the amount of the polymer additives is less than 0.5 wt %, it is difficult to effectively enhance the coverage on the perovskite material layer to improve the electron transfer efficiency of the planar heterojunction solar cells. On the other hand, when the amount of the polymer additives is more than 3 wt %, the excess polymer additives may hinder the electron or hole transport efficiency in the perovskite material layer, thus failing to improve the photoelectric conversion efficiency of solar cells. The amount of the polymer additives is preferably from 1 to 3 wt %.

Due to the addition of the polymer additive, the surface roughness of the perovskite material layer can be controlled within 50 to 100 nm. In the solar cell having the planar heterojunction structure of the present invention, the perovskite material layer having a lower surface roughness can ensure a good contact interface with other layers, thus enhancing the electrons or hole transfer efficiency. The surface roughness of the perovskite material layer is preferably from 60 to 80 nm. The present invention also provides a method for preparing the above perovskite solar cell, comprising: (A) providing a first electrode substrate; (B) providing a perovskite material layer over the first electrode substrate, wherein the perovskite material layer includes an organic-inorganic perovskite material layer and a polymer additive; and (C) providing a second electrode over the perovskite material layer.

The above method for preparing the perovskite solar cell may further include a step (A′) providing a first electron transport layer over the first electrode substrate, such that the electron transport layer is disposed between the first electrode substrate and the perovskite material layer.

The above method for preparing the perovskite solar cell may further include a step (C′) providing a hole transport layer over the perovskite material layer, such that the hole transport layer is interposed between the perovskite material layer and the second electrode.

According to a preferred embodiment of the present invention, in the step (B) of the above method, the method for preparing the above perovskite solar cell may further include a step (B1) forming a perovskite material precursor, wherein the perovskite material precursor may include a mixture of an alkylammonium iodide (such as methylammonium iodide), a metal halide (such as PbCl₂), a polymer additive (such as polyethylene glycol), and a solvent (such as dimethyl formamide (DMF)); (B2) spin-coating the perovskite material precursor on the first electrode substrate or the electron transport layer; and (B3) thermally-treating the perovskite material precursor to form a perovskite material layer.

In the present specification, the term “over” means in an direction, and it may comprise adjoining and non-adjoining elements as well as non-overlapping and overlapping elements, and these elements may be in direct contact or not. For example, the perovskite material layer disposed over the first electrode substrate may indicate not only the direct contact of the perovskite material layer and the first electrode substrate, but also, a non-contact state of the two layers (i.e., with one or more intervening layers).

### BRIEF DESCRIPTION OF THE DRAWINGS

FIG. 1 shows a schematic diagram of the perovskite solar cell according to Example 1 of the present invention.

FIG. 2 shows an SEM image of the perovskite material layer according to Example 1 of the present invention.

FIG. 3 shows an SEM image of the perovskite material layer according to Example 2 of the present invention. FIG. 4 shows an SEM image of the perovskite material layer according to Comparative Example 1 of the present invention.

FIG. 5 shows an SEM image of the perovskite material layer according to Comparative Example 2 of the present invention.

FIG. 6 shows an X-ray diffraction spectra according to Examples 1-2 and Comparative Examples 1-2 of the present invention.

FIG. 7 shows a schematic diagram of the photoelectric properties according to Examples 1-2 and Comparative Examples 1-2 of the present invention.

### DETAILED DESCRIPTION OF THE PREFERRED EMBODIMENT

### Example 1

First, 0.399 g of methylammonium iodide, 0.233 g of lead chloride (PbCl₂), and 6.32 mg of polyethylene glycol (1 wt %) (molecular weight: 6000) were dissolved in 1 mL of dimethyl formamide (DMF), and uniformly stirred at room temperature to prepare a perovskite material precursor. Then, a solution containing TiO₂ nanoparticles was prepared using a solvent of 2-methoxyethanol, and the content of TiO₂ nanoparticles was 10mg/mL Furthermore, 80 mg of spiro-OMeTAD, 28.5 mL of 4-tert-butylpyridine and 17.5 μL of Li-TFSI solution were dissolved in 1 mL of chlorobenzene to prepare a solution comprising spiro-OMeTAD.

Next, a FTO substrate was used as a first electrode substrate, and the above solution containing the TiO₂ nanoparticles was spin-coated (3000 rpm, 40 seconds) on the FTO substrate, followed by a thermal treatment at a temperature of 150° C. for 30 minutes, to form the TiO₂ layer as an electron transport layer. Then, the above perovskite material precursor containing 1 wt % of polyethylene glycol was spin-coated (2000 rpm, 40 seconds) on the TiO₂ layer, followed by a thermal treatment at a temperature of 100° C. for 1 hour, to form a perovskite material layer (including CH₃NH₃PbI₃₋ₙClₙ and polyethylene glycol). After that, the solution containing spiro-OMeTAD was spin-coated (4000 rpm, 30 seconds) on the perovskite substrate, to form a hole transport layer. Finally, a 100 nm-thick gold film was coated on the hole transport layer to serve as the second electrode by vapor deposition. As such, a perovskite solar cell was completed.

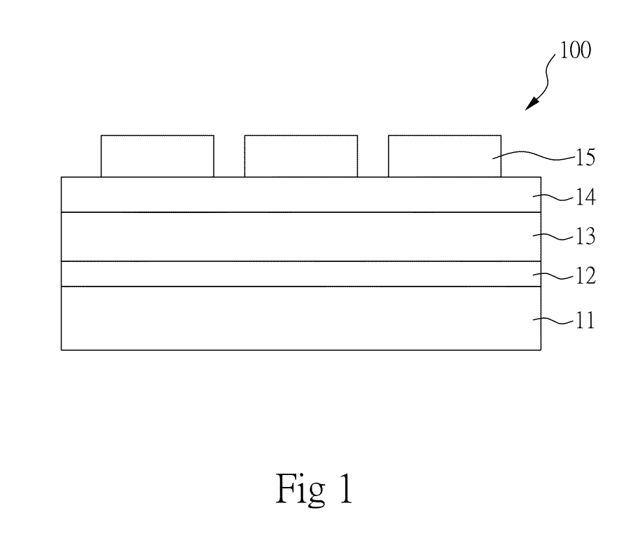

The configuration of the perovskite solar cell 100 prepared by the method of the this example was shown in FIG. 1, including a first electrode substrate 11, an electron transport layer 12, a perovskite material layer 13, a hole transport layer 14, and a second electrode 15, which were sequentially laminated.

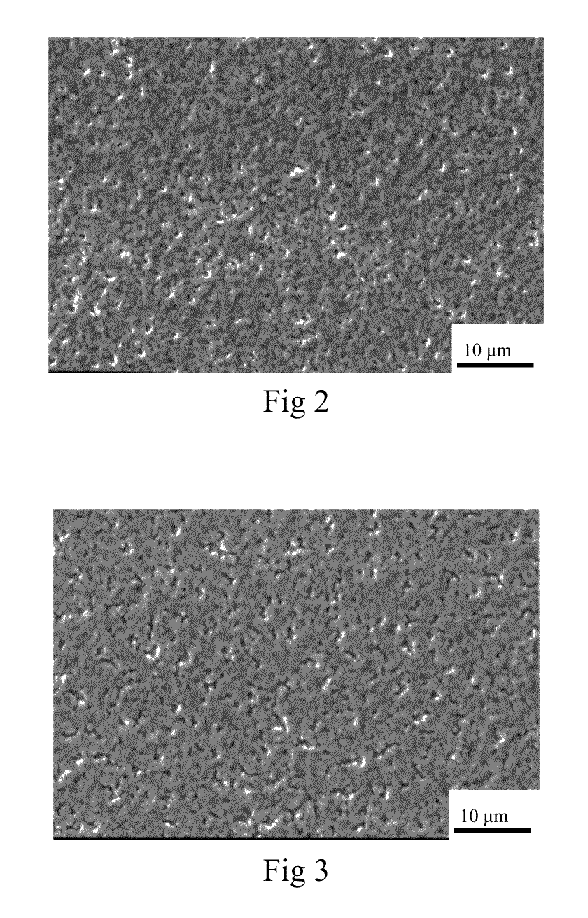

In addition, in this example, the prepared perovskite material layer was shown in FIG. 2, and it can be observed that the perovskite material layer had a very excellent coverage.

### Example 2

The perovskite solar cell prepared in this example was substantially the same as in Example 1, except that in the perovskite material layer, 3 wt % of polyethylene glycol was included as the polymer additive. In this example, the prepared perovskite material layer was shown in FIG. 3, and it can also be observed that the perovskite material layer had a very excellent coverage.

### Comparative Example 1

The perovskite solar cell prepared in this example was substantially the same as in Example 1, except that in the perovskite material layer, the polymer additive was not added. In this example, the prepared perovskite material layer was shown in FIG. 4, and it can be observed that the perovskite material layer had a poor excellent coverage, and a large area of the underlying electron transport layer was exposed.

### Comparative Example 2

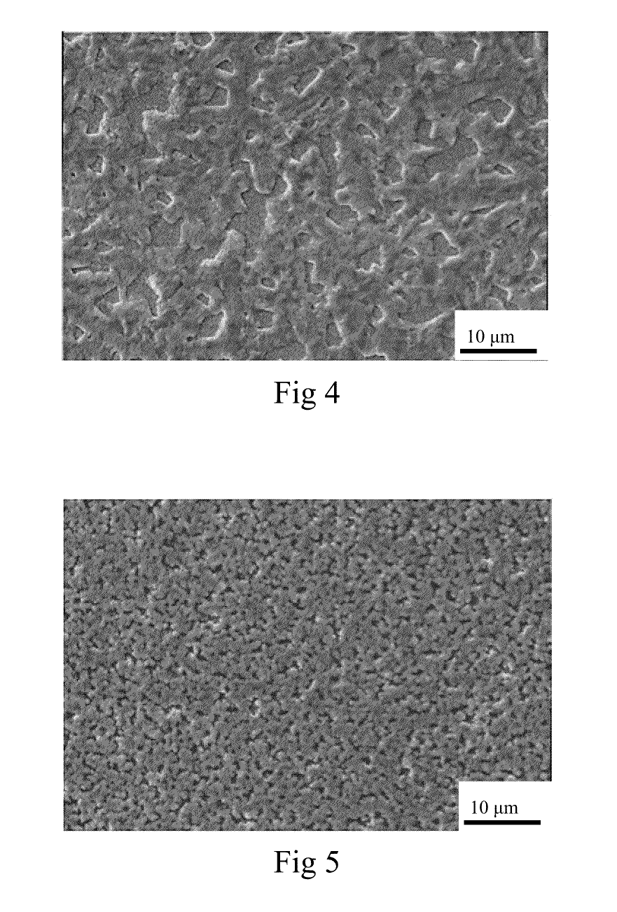

The perovskite solar cell prepared in this example was substantially the same as in Example 1, except that in the perovskite material layer, 5 wt % of polyethylene glycol was included as the polymer additive. In this example, the prepared perovskite material layer was shown in FIG. 5.

### Test Example 1: X-Ray Diffraction Analysis

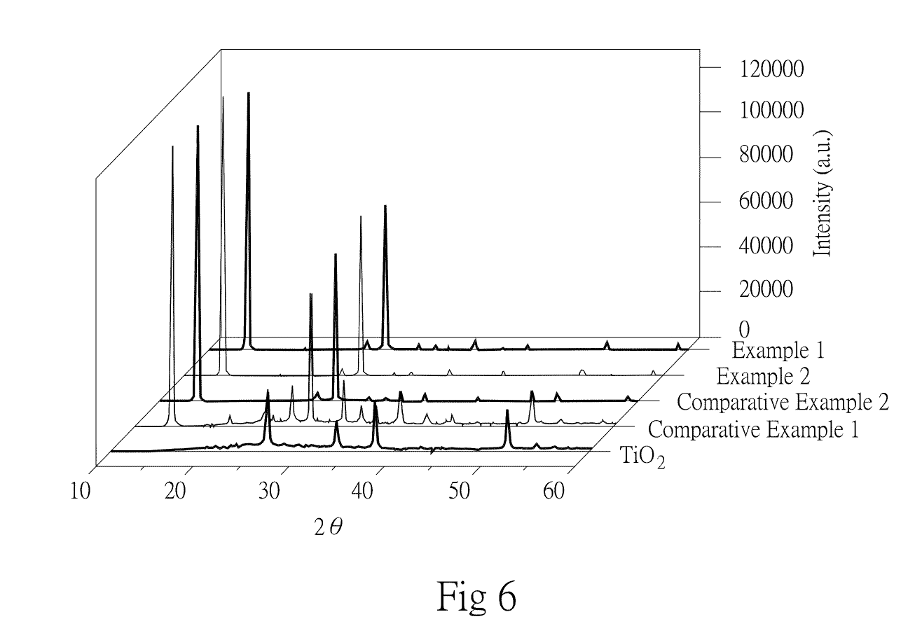

In this Test Example, the coverage of the perovskite material layers prepared in Examples 1-2 and Comparative Examples 1-2 layer on the TiO₂ layer was observed by X-ray diffraction analysis. The semi-finished products containing the sequentially laminated FTO substrate, TiO₂ layer, and perovskite material layer of the above Examples and Comparative Example were subjected to X-ray diffraction analysis, and the results are shown in FIG. 6. The results shown in FIG. 6 indicate that the perovskite material layer with the polyethylene glycol as the additive can effectively shield the underlying TiO₂ layer, while the perovskite material layer without the polymer additive in the Comparative Examples cannot effectively shield the TiO₂ layer (marked by *). Therefore, the polymer additive can effectively enhance the coverage of perovskite material layer.

### Test Example 2: Roughness Analysis

In this Test Example, the surface roughness of the perovskite material layers prepared in Examples 1-2 and Comparative Examples 1-2 layer was analyzed by atomic force microscopy system (AFM). Same as Test Example 1, semi-finished products of the sequentially laminated FTO substrate, TiO₂ layer, and perovskite material layer were subjected to the analysis, and the results are shown in Table 1.

### Test Example 3: Photoelectric Properties

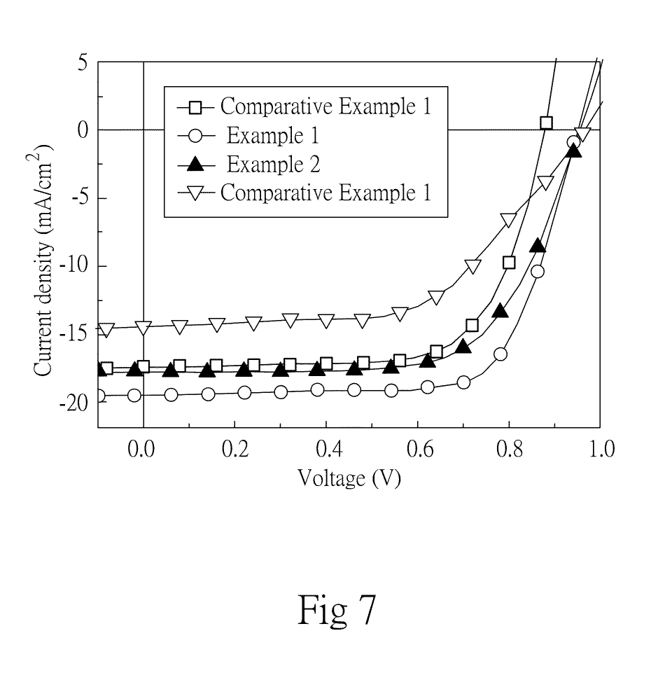

In this Test Example, the photoelectric properties of the perovskite solar cells prepared in Examples 1-2 and Comparative Examples 1-2 were tested. First, AM1.5G solar stimulator was employed to provide 100 mW/cm² of an incident light source, followed by scanning using a Keithley 2410 power meter. The analysis results are shown in FIG. 7 and Table 1.

TABLE 1

| | | | | | | PCE | |
|---|---|---|---|---|---|---|---|
| | Rms | Voc | Jsc | FF | PCE | maximum | Rs |
| | (nm) | (V) | (mA/cm²) | (%) | (%) | (%) | (Ωcm²) |
| Example 1 | 73.04 | 0.94 ± 0.01 | 19.53 ± 0.16 | 70.35 ± 1.35 | 12.90 ± 0.21 | 13.20 | 7.82 ± 1.13 |
| Example 2 | 73.51 | 0.97 ± 0.01 | 17.89 ± 0.10 | 62.21 ± 3.79 | 10.79 ± 0.46 | 11.23 | 13.59 ± 4.17 |
| Comparative | 106.63 | 0.88 ± 0.01 | 17.28 ± 0.16 | 69.28 ± 0.64 | 10.47 ± 0.09 | 10.58 | 5.82 ± 0.41 |
| Example 1 | | | | | | | |
| Comparative | 65.39 | 0.96 | 14.41 | 55.97 | 7.77 | 7.77 | 19.73 |
| Example 2 | | | | | | | |

Rms: Surface roughness
Voc: open circuit voltage
Jsc: short circuit current density
FF: fill factor
PCE: photoelectric conversion efficiency
Rs: series resistance

The above analysis results indicate that in the formation of the perovskite material layer, an appropriate amount of polymer additives can be added to help evenly disperse the organic-inorganic perovskite material on a substrate, preventing the material from crystallization, such that the organic-inorganic perovskite material may be formed into a continuous film on the substrate to absorb more light and efficiently transport the charges, thereby enhancing the photoelectric conversion efficiency. However, when the content of the polymer additive is excessive, phase separation may occur between the polymer additive and the organic-inorganic perovskite material, thus failing to form a continuous perovskite material layer, and the charge cannot be transported efficiently, thereby leading to a reduced photoelectric conversion efficiency.

Accordingly, when an appropriate amount of the polymer additive is added, particularly 1 to 3 wt % of the polymer additive, the photoelectric conversion efficiency of the perovskite solar cell can be improved. For example, in the perovskite material layer, when the content of the polymer additive is 1 wt %, the photoelectric conversion efficiency can be increased from 10.58% to 13.20%.

Although the present invention has been explained in relation to its preferred embodiment, it is to be understood that many other possible modifications and variations can be made without departing from the spirit and scope of the invention as hereinafter claimed.

What is claimed is:

1. A perovskite solar cell, comprising:
a first electrode substrate;
a perovskite material layer comprising a perovskite organic-inorganic material and a polymer additive, wherein the perovskite material layer is disposed above the first electrode substrate; and
a second electrode, which is disposed above the perovskite material layer and corresponds to the first electrode substrate.

2. The perovskite solar cell of claim 1, further comprising an electron transport layer between the first electrode substrate and the perovskite material layer, and the electron transport layer is made of an inorganic material, n-type organic small molecules, or n-type polymers.

3. The perovskite solar cell of claim 1, wherein the electron transport layer is selected from the group consisting of: titanium oxide (TiO₂), zinc oxide (ZnO), indium tin oxide (InSnOx), copper oxide (CuOx), alumina (Al₂O₃), zirconium oxide (ZrO₂), tin oxide (SnO₂), tungsten oxide (WO₃), niobium oxide (Nb₂O₅), cadmium sulfide (CdS), cadmium selenide (CdSe), cadmium telluride (CdTe), bismuth sulfide (Bi₂S₃), lead sulfide (PbS), and indium phosphide (InP).

4. The perovskite solar cell of claim 1, further comprising a hole transport layer between the second electrode and the perovskite material layer, and the hole transport layer is made of an inorganic material, p-type organic small molecules, or p-type polymers.

5. The perovskite solar cell of claim 4, wherein the hole transport layer is selected from the group consisting of: 2,2′,7,7′-tetrakis(N,N-p-dimethoxyphenylamino)-9,9-spirobifluorene (spiro-OMeTAD), poly(3,4-ethylenedioxythiophene)-poly(styrenesulfonate (PEDOT-PSS), N,N′-bis(3-methylphenyl)-N,N′-bis(phenyl)benzidine (TPD), and poly(3-hexylthiophene) (P3HT).

6. The perovskite solar cell of claim 1, wherein the first electrode substrate is a transparent electrode selected from the group consisting of:
fluorine doped tin oxide (FTO), indium tin oxide (ITO), ZnO—Ga₂O₃, ZnO—Al₂O₃, tin oxide, and zinc oxide.

7. The perovskite solar cell of claim 1, wherein the second electrode is selected from the group consisting of: copper, gold, silver, rubidium, palladium, nickel, molybdenum, aluminum, alloys thereof, and multi-layer materials comprising the same.

8. The perovskite solar cell of claim 1, wherein the perovskite organic-inorganic material is selected from at least one of the compounds represented by Formula (I):
R₁R₂R₃NMX₃₋ₙYₙ (I)
wherein, R₁, R₂, and R₃ are each independently H, a linear C₁₋₁₀ alkyl , or branched C₁₋₁₀ alkyl;
M is Pb, Sn, Bi, Cu, Fe, Co, Ni, Mn, or Cd;
X and Y are each independently Cl, Br, or I; and
n is an integer of 0-3.

9. The perovskite solar cell of claim 8, wherein the perovskite organic-inorganic material is CH₃NH₃PbI₃₋ₙClₙ, wherein n is an integer of 0-3.

10. The perovskite solar cell of claim 1, wherein the polymer additive comprises at least one hydrophilic polymer.

11. The perovskite solar cell of claim 10, wherein the hydrophilic polymer is at least one selected from the group consisting of: polyethylene glycol, polypropylene glycol, polyvinyl pyrrolidone, polylactic acid, polyvinyl alcohol, polyacrylic acid, polyurethane, polyethylene imine, polyacrylamide, poly(styrene sulfonic acid), and mixtures thereof.

12. The perovskite solar cell of claim 10, wherein the hydrophilic polymer has a molecular weight of 2K to 60K.

13. The perovskite solar cell of claim 1, wherein, in the perovskite material layer, the polymer additives is present in an amount of 0.5 to 3 percent by weight.

14. The perovskite solar cell of claim 1, wherein the perovskite material layer has a surface roughness of 50-100 nm.
